(19) United States
(12) Patent Application Publication
(10) Pub. No.: US 2012/0144091 A1
(43) Pub. Date: Jun. 7, 2012

(54) Mask-Programmed Read-Only Memory with Reserved Space

(76) Inventor: Guobiao ZHANG, Corvallis, OR (US)

(21) Appl. No.: 13/396,596

(22) Filed: Feb. 14, 2012

Related U.S. Application Data
(63) Continuation-in-part of application No. 12/883,172, filed on Sep. 15, 2010, now abandoned.
Application No. 12/883,172 is a continuation-in-part of application No. 11/736,773, filed on Apr. 18, 2007, now abandoned.
(60) Provisional application No. 60/884,618, filed on Jan. 11, 2007.

(51) Int. Cl. G06F 12/00; G11C 17/00

(52) U.S. Cl. 711/102; 365/103; 711/E12.001

(57) ABSTRACT

The present invention discloses a mask-ROM with reserved space (mask-ROM_{RS}). On its original data-mask, at least one mask-region is reserved for the new contents and contains no patterns. The present invention further discloses a 3-D mask-ROM with reserved memory level(s) (3D-MPROM_{RL}). At least one memory level is reserved for the new contents and not manufactured in the original 3D-MPROM_{RL}. By avoiding mask replacement, the present invention minimizes extra mask cost due to content revision.

### CROSS-REFERENCE TO RELATED APPLICATIONS

[Para 1] This application is a continuation-in-part of U.S. patent application Ser. No. 12/883,172, “Three-Dimensional Mask-Programmable Memory with Reserved Space”, filed Sep. 15, 2010, which is a continuation-in-part of U.S. patent application Ser. No. 11/736,773, “Mask-Programmable Memory with Reserved Space”, filed Apr. 18, 2007, which is related to a U.S. Patent Application Ser. No. 60/884,618, “Mask-Programmable Memory with Reserved Space”, filed Jan. 11, 2007.

### BACKGROUND

1. Technical Field of the Invention

The present invention relates to the field of integrated circuits, and more particularly to mask-programmed read-only memory (mask-ROM).

2. Prior Arts

For a mask-programmed read-only memory (mask-ROM), contents are programmed during manufacturing through at least one data-mask whose patterns represent the content data. When new contents are released, a newer version of the mask-ROM needs to be manufactured. Because the mask patterns, once written, cannot be modified, the conventional mask-ROM generally requires mask replacement for content revision, i.e. discarding the original data-mask and replacing it with a new data-mask.

FIG. 1A illustrates an original data-mask 2, which is used to program an original mask-ROM. It comprises a plurality of mask-regions (2a . . . ), whose patterns represent contents (4a . . . ). These contents can be categorized into permanent contents (4a-4d, 4f-4i) and out-of-date contents (4e). During content revision, the permanent contents (4a-4d, 4f-4i) do not change, while the out-of-date contents (4e) are changed to up-to-date contents (4e*). FIG. 1B illustrates the new data-mask 2x, which replaces the original data-mask 2. It is used to program a newer version of the mask-ROM. The content stored in the mask-region 2e is now the up-to-date content 4e*, while the permanent contents stored in the mask-regions 2a-2d, 2f-2i remain the same.

Mask replacement for content revision is acceptable when the data-mask contains a small amount of contents, e.g. only the out-of-date contents. However, this practice becomes wasteful when the original data-mask contains a lot of permanent contents which are still usable in the newer version of the mask-ROM. Because a new data-mask costs hundreds of thousands of dollars, discarding a whole data-mask due to a small revision on the data-mask will significantly increase the mask-ROM cost. To overcome this and other drawbacks, the present invention discloses a mask-ROM with reserved space (mask-ROM_{RS}).

### OBJECTS AND ADVANTAGES

It is a principle object of the present invention to provide a mask-ROM that can economically accommodate content revision.

It is a further object of the present invention to provide a mask-ROM which minimizes extra mask cost due to content revision.

It is a further object of the present invention to provide a mask-ROM which avoids mask replacement due to content revision.

In accordance with these and other objects of the present invention, a mask-ROM with reserved space (mask-ROM_{RS}) is disclosed.

### SUMMARY OF THE INVENTION

The present invention discloses a mask-ROM with reserved space (mask-ROM_{RS}). On its original data-mask, at least one mask-region is reserved for the new contents and contains no patterns. This reserved mask-region can be used to write the mask patterns of the new contents in the updated mask-ROM_{RS}. Accordingly, the mask-ROM_{RS} comprises an original data space and a reserved space. The original data space stores the original contents and does not change between different versions of the mask-ROM_{RS}. On the other hand, the reserved space, which is originally empty, stores the new contents in the updated mask-ROM_{RS}. Because the data-mask is only modified, but not replaced, the mask-ROM_{RS} incurs little extra mask cost for content revision.

The present invention further discloses a three-dimensional mask-ROM with reserved memory level(s) (3D-MPROM_{RL}). When fully manufactured, a 3D-MPROM_{RL} comprises X (X is a positive integer) memory levels, among which the topmost Y (Y is a positive integer, Y<X) memory levels are reserved for the new contents. The 3D-MPROM_{RL} only contains enough memory levels for the required contents. To be more specific, the original 3D-MPROM_{RL} is partially manufactured and comprises only the lowermost Z (Z is a positive integer, Z=X−Y) memory levels (i.e. original memory levels), which store the original contents. The updated 3D-MPROM_{RL} is fully manufactured and comprises all X memory levels, with the reserved Y memory levels formed on top of the original Z memory levels and storing the new contents. Note that the original 3D-MPROM_{RL}, even though partially manufactured, is fully functional and can be read by a data-reading device. In addition, even though the reserved memory levels are absent in the original 3D-MPROM_{RL}, their peripheral circuits are still formed in the substrate, because the substrate circuits for all versions of the 3D-MPROM_{RL} are defined by the same mask set.

### BRIEF DESCRIPTION OF THE DRAWINGS

FIGS. 1A-1B illustrate the original and new data-masks used in the prior-art mask-ROM;

FIGS. 2A-2B illustrate the original and updated data-masks used in a preferred mask-ROM_{RS};

FIGS. 3A-3B disclose the original and updated pointer files for the preferred mask-ROM_{RS} of FIGS. 2A-2B;

FIGS. 4A-4B illustrate the original and updated data-masks used in another preferred mask-ROM_{RS};

FIGS. 5A-5B disclose the original and updated pointer files for the preferred mask-ROM_{RS} of FIGS. 4A-4B;

FIGS. 6A-6B disclose the original and updated file systems for a preferred mask-ROM_{RS};

FIGS. 7A-7B disclose the original and updated MBR pointer tables;

FIG. 8A is a cross-sectional view of a preferred 3D-MPROM with reserved space (3D-MPROM_{RS}) in its original version; FIG. 8B is a top view of the original data-mask at the memory level 200;

FIG. 9A is a cross-sectional view of the updated 3D-MPROM_{RS}; FIG. 9B is a top view of the updated data-mask at the memory level 200;

FIG. 10A is a cross-sectional view of a preferred 3D-MPROM with reserved memory level(s) (3D-MPROM_{RL}) in its original version; FIG. 10B is a top view of its substrate;

FIG. 10C is its circuit block diagram; FIG. 10D illustrates the data-mask for its first memory level; FIG. 10E discloses its pointer file;

FIG. 11A is a cross-sectional view of the updated 3D-MPROM_{RL}; FIG. 11B is its circuit block diagram; FIG. 11C illustrates the data-mask for its second memory level; FIG. 11D discloses its pointer file.

For reason of simplicity, diodes, transistors and other memory components are not shown in these figures. In this specification, the term “original” refers to that of the first (original) version of the mask-ROM, and the term “updated” refers to that of the newer (updated) version of the mask-ROM.

### DETAILED DESCRIPTION OF THE PREFERRED EMBODIMENTS

Those of ordinary skills in the art will realize that the following description of the present invention is illustrative only and is not intended to be in any way limiting. Other embodiments of the invention will readily suggest themselves to such skilled persons from an examination of the within disclosure.

The present invention discloses a mask-ROM with reserved space (mask-ROM_{RS}). On its original data-mask, at least one mask-region is reserved for the new contents and contains no patterns. This reserved mask-region can be used to write the mask patterns of the new contents in the updated mask-ROM_{RS}. Accordingly, the mask-ROM_{RS} comprises an original data space and a reserved space. The original data space stores the original contents and does not change between different versions of the mask-ROM_{RS}. On the other hand, the reserved space, which is originally empty, stores the new contents in the updated mask-ROM_{RS}. Because the data-mask is only modified, but not replaced, the mask-ROM_{RS} incurs little extra mask cost for content revision.

In the present invention, “content” can be broadly interpreted as a standalone content or a component of a standalone content. Here, “standalone content” refers to information which, by itself, provides value for an end-user in specific context. A content could be a single file or a collection of files. One example of content is a multimedia content (e.g. a movie or a TV program) or a component file thereof (e.g. the video file of a movie). Another example is a computer program (e.g. a video game) or a component file thereof (e.g. an object file or a library file of a video game).

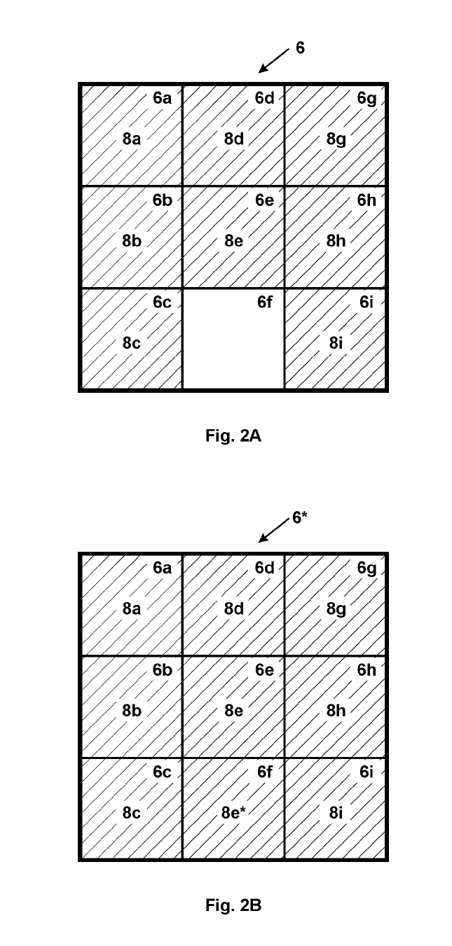

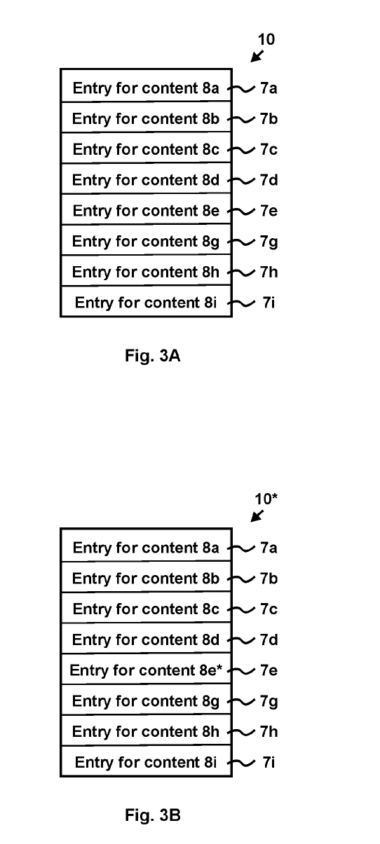

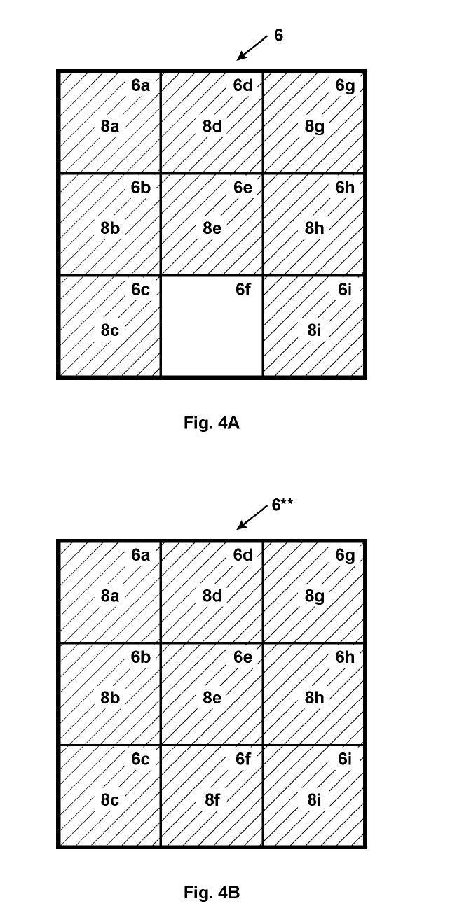

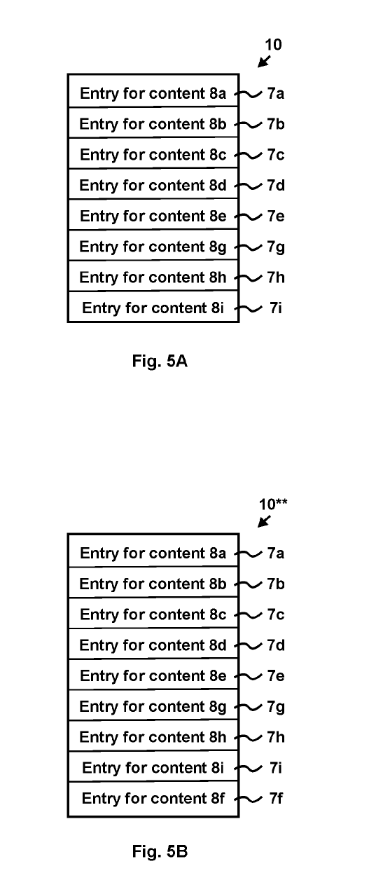

In general, content revision includes content replacement and content addition. In the following figures, FIGS. 2A-3B illustrate a preferred mask-ROM_{RS} suitable for content replacement, where an out-of-date content 8e is replaced by an up-to-date content 8e*; whereas, FIGS. 4A-5B illustrate another preferred mask-ROM_{RS} suitable for content addition, where an extra content 8f is added to, but not to replace, the original contents.

Referring now to FIG. 2A, an original data-mask 6 for a preferred mask-ROM_{RS} is disclosed. It comprises a plurality of mask-regions (6e . . . ). The shaded mask-regions 6a-6e, 6g-6i store contents 8a-8e, 8g-8i, respectively. Note that the original content 8e will become out-of-date when the new contents are released, e.g. content 8e is to be replaced by content 8e*. On the other hand, the blank mask-region 6f contains no patterns, i.e. it is either fully dark or fully clear. Hence, the mask-region 6f is a reserved mask-region.

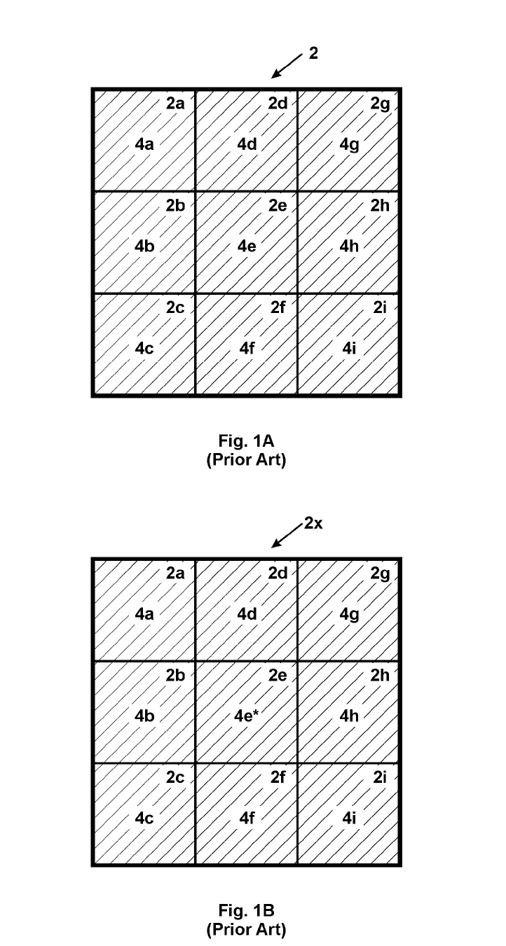

FIG. 2B illustrates an updated data-mask 6*. This updated data-mask 6*, instead of being a completely new mask, is modified from the original data-mask 6. The mask patterns for the up-to-date content 8e* is written into the reserved mask-region 6f, as it originally contains no patterns. Because much less data are written, the updated data-mask 6* costs much less than the new data-mask 2x of FIG. 1B.

FIGS. 3A-3B disclose the original and updated pointer files for the preferred mask-ROM_{RS} of FIGS. 2A-2B. A pointer file comprises a collection of pointers for the contents in a memory. It could be a directory file (e.g. a root directory table) when the contents are standalone contents; or, a linker when the contents are component files of a standalone content. In the preferred embodiment, the pointer file (e.g. 10) comprises a plurality of entries (7e . . . ), with each entry including a pointer to the memory address of a content 8e (e.g. its starting address). In the updated pointer file 10*, the entries 7a-7d, 7g-7i remain the same. However, instead of pointing to the out-of-date content 8e, the entry 7e points to the up-to-date content 8e*. When accessing the content 8e, the up-to-date content 8e* is read out.

Referring now to FIGS. 4A-4B, an original data-mask 6 and an updated data-mask 6** for another preferred mask-ROM_{RS} are disclosed. This preferred embodiment is suitable for content addition. The original data-mask 6 is same as that of FIG. 2A. When an extra content 8f is added to the original contents, the data-mask 6 is modified and the mask patterns for the extra content 8f are written into the reserved mask-region 6f.

FIGS. 5A-5B disclose the original and updated pointer files for the preferred mask-ROM_{RS} of FIGS. 4A-4B. In this preferred embodiment, the pointer file is a directory file (e.g. a root directory table). The original pointer file 10 is same as that of FIG. 3A. In this preferred embodiment, the extra content 8f is added to, but not to replace, the original contents. Accordingly, the updated pointer file 10** comprises a new entry 7f pointing to the extra content 8f. To access the extra content 8f, the updated pointer file 10** is searched and the extra content 8f is accessed via the pointer in the new entry 7f.

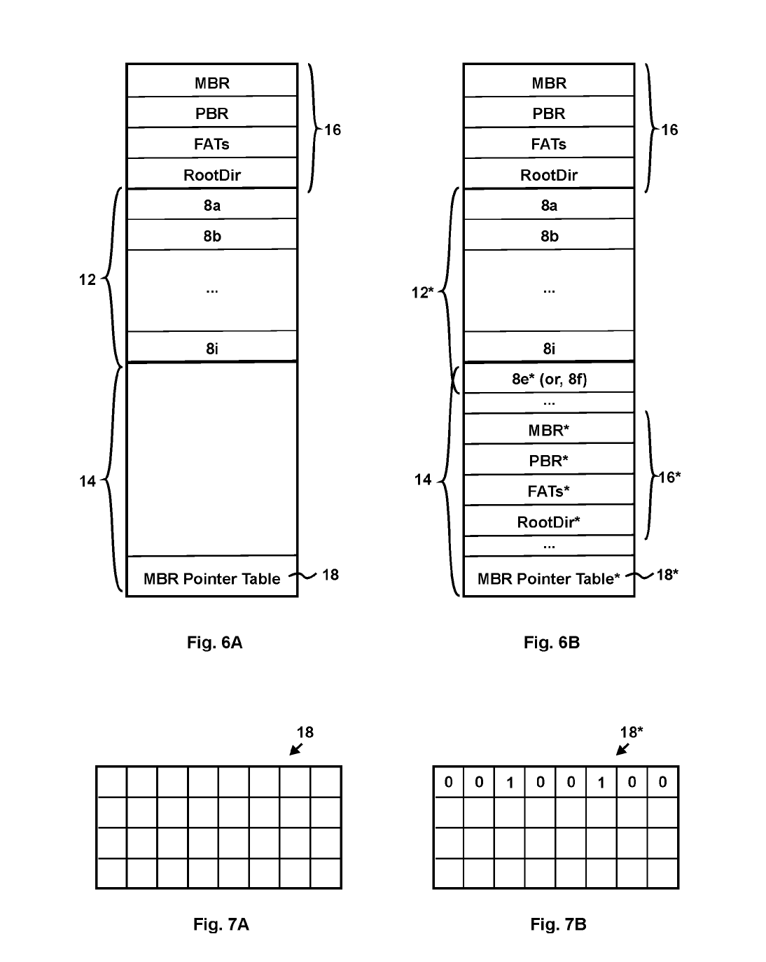

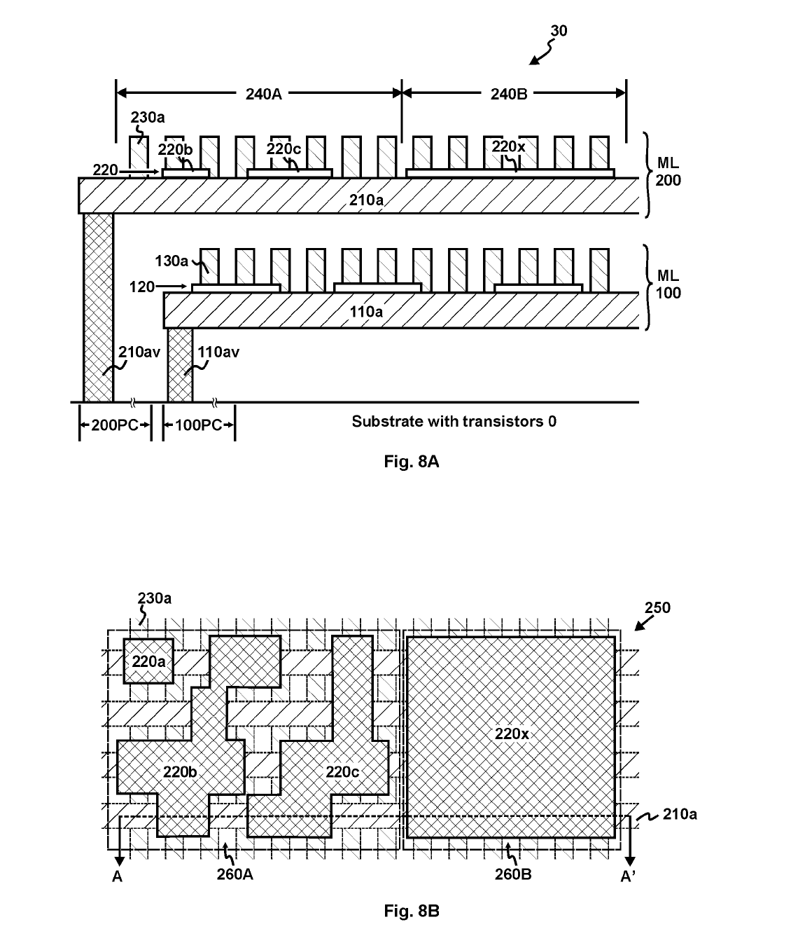

Content revision involves not only updating the content data, but also updating the file system. Due to the prevalence of data-reading devices using write-many file system (e.g. FAT file system), it is desirable that the data in the mask-ROM_{RS} can be read by a data-reading device using write-many file system. FIGS. 6A-7B disclose an exemplary file system and the associated MBR pointer table for a preferred mask-ROM_{RS}.

Referring now to FIGS. 6A-6B, the original and updated file systems of a preferred mask-ROM_{RS} are disclosed. These figures are drawn in the logical address space and show logical organizations of the original and updated mask-ROM_{RS}'s. The file system of the mask-ROM_{RS} comprises at least a file system structure (e.g. 16). Similar to that of a write-many file system, this file system structure comprises MBR (master boot record), PBR (partition boot record), FAT (file allocation table) and RootDir (root directory table).

The original file system of FIG. 6A comprises an original file system structure 16, an original data space 12 and a reserved space 14. The original data space 12 comprises the data for the original contents (8a . . . ). The reserved space 14 is empty. It comprises all empty blocks in the original mask-ROM_{RS}. Here, “block” is the smallest data allocation unit of a memory in the logical address space; and “empty” means this data block is not programmed, e.g. every bit in the empty block is “0”. It should be noted that the mask patterns corresponding to the empty blocks of the reserved space form the reserved mask-regions of the data-mask.

The updated file system of FIG. 6B comprises an updated data space 12*, which includes the new content 8e* (or, 8f), as well as the original contents (8a . . . ). It further comprises the original files system structure 16 and the updated file system structure 16*. This is different from that of a write-many memory. The file system of a write-many memory comprises only a single file system structure, because the original file system structure can be overwritten by the updated file system structure. In a mask-ROM, with no data-overwriting possible, the updated file system structure 16* has to be stored in another memory location.

In the updated mask-ROM_{RS}, the new content 8e* (or, 8f) is stored in the reserved space 14. In the case of content addition, the reserved space 14 should be large enough to store at least one standalone content. Considering the large storage space required by a movie, a TV program or a video game, the reserved space needs to be larger than 30 MB, preferably larger than 100 MB.

To indicate to a data-reading device the memory location of the most up-to-date file system structure, the preferred mask-ROM_{RS} further comprises an MBR pointer table, which records the MBR address for every version of the mask-ROM_{RS}. A portion of the reserved space 14 is allocated for this purpose.

FIGS. 7A-7B disclose an exemplary MBR pointer table. In these drawings, a line of eight bits is shown to simplify the drawings, and each non-zero entry (i.e. a line contains at least one non-zero bit) corresponds to a pointer. FIG. 7A shows the original MBR pointer table 18. Since the original MBR starts from address zero, a pointer is not written to the MBR pointer table 18 and therefore, all lines are empty. FIG. 7B shows the updated MBR pointer table 18*. The first line is the only non-zero entry and it indicates the memory address of the updated MBR. Because no data can be overwritten in the mask-ROM_{RS}, the memory address of any future version of the MBR pointer is written into a new line of the MBR pointer table.

When a data-reading device is connected with the mask-ROM_{RS}, the controller for the mask-ROM_{RS} queries the MBR pointer table first to read the last line of the non-zero entry. This will be used as the address when the data-reading device sends a request to read address zero of the mask-ROM_{RS}. As a result, the subsequent requests for the MBR are redirected to the location indicated by this last non-zero entry. It should be noted that besides the file system disclosed in FIGS. 6A-7B, many other file systems are possible. For example, the file system for a write-once memory disclosed in the U.S. Pat. No. 7,062,602 can also be used in the mask-ROM_{RS}.

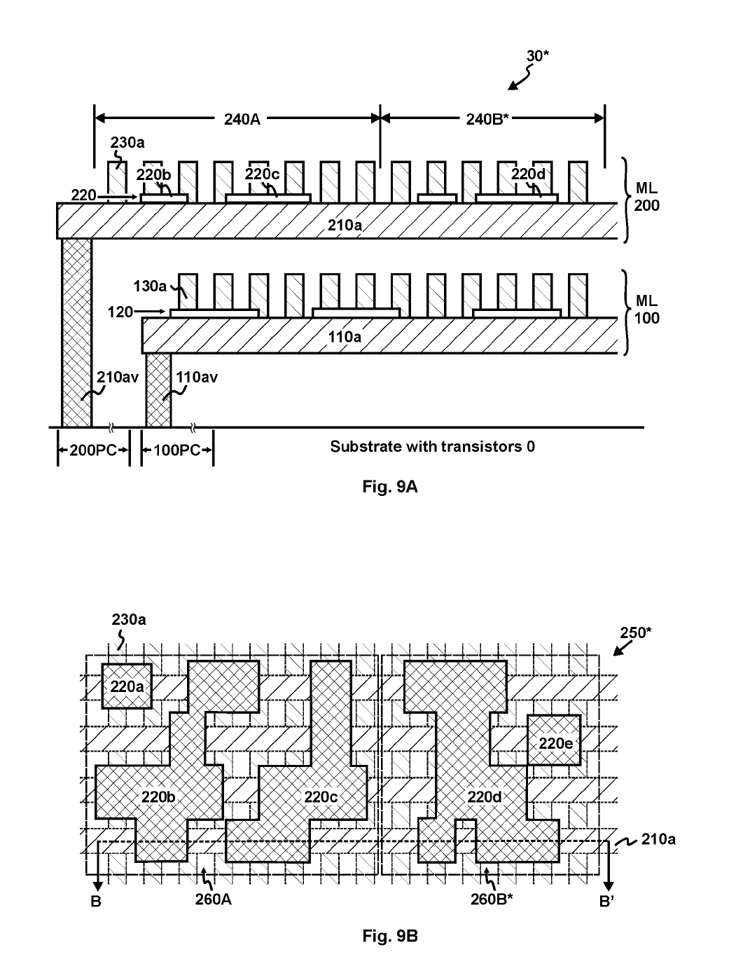

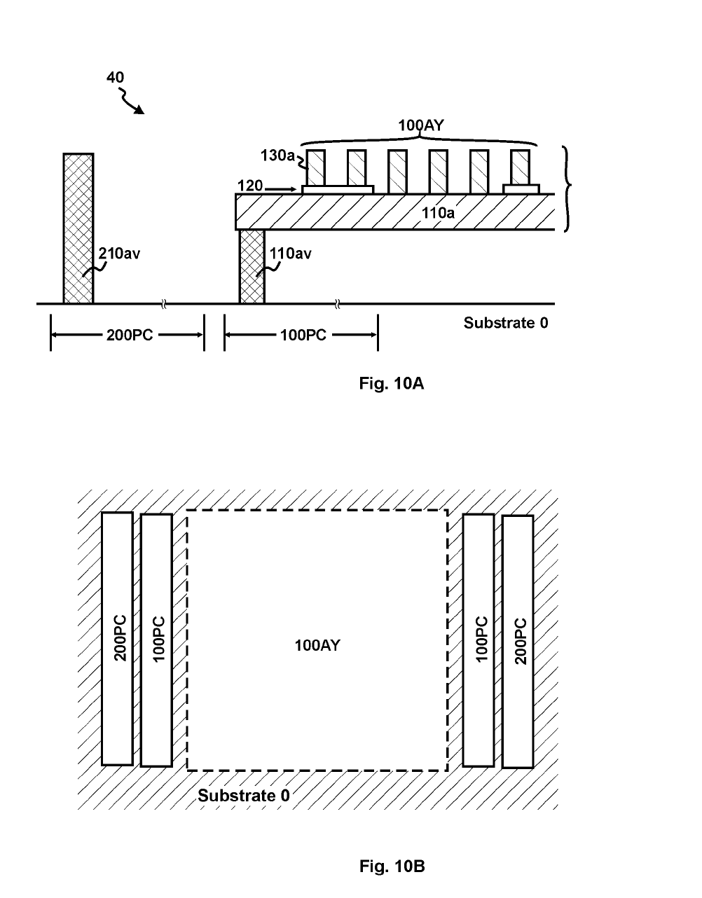

Mask-ROM_{RS} can be applied to three-dimensional mask-ROM (3D-MPROM). As disclosed in U.S. Pat. No. 5,835,396, a 3D-MPROM comprises a plurality of vertically stacked memory levels (i.e. mask-ROM levels). FIGS. 8A-9B illustrate a 3D-MPROM with reserved space (3D-MPROM_{RS}). In this example, two physical memory levels 100, 200 are stacked one by one on a semiconductor substrate 0. Each memory level (e.g. 200) comprises a plurality of address lines (210a . . . ; 230a . . . ) and memory cells (i.e. mask-ROM cells). Each memory level further comprises at least a data-layer 220, which determines the digital state of memory cells. Examples of the data-layer include an insulating dielectric and a resistive layer. The patterns of the data-layer are defined by at least one data-mask (e.g. 250 of FIG. 8B and 250* of FIG. 9B). The semiconductor substrate 0 comprises a substrate circuit. The substrate circuit includes the peripheral circuits 100PC, 200PC for the memory levels 100, 200. Contact vias (110av, 210av) couple the memory levels (100, 200) with their respective peripheral circuit in the substrate.

FIG. 8A is a cross-sectional view of the original 3D-MPROM_{RS} 30 along the cut-line AA′ of FIG. 8B; while FIG. 8B is a top view of the original data-mask 250 for the memory level 200 and its relative placement with respect to the address lines (210a . . . ; 230a . . . ). Here, the memory cells at the memory level 100 and in the area 240A of the memory level 200 form the original data space, which stores the original contents. The mask-region 260B on the original data-mask 250 contains no patterns and therefore, is a reserved mask-region. Accordingly, the memory cells in the area 240B of the memory level 200 store empty blocks and form a reserved space.

FIG. 9A is the cross-sectional view of the updated 3D-MPROM_{RS} 30* along the cut-line BB′ of FIG. 9B; while FIG. 9B is the top view of the updated data-mask 250* for the memory level 200 and its relative placement with respect to the address lines (210a . . . ; 230a . . . ). Here, the original data space remains the same between two versions of the 3D-MPROM_{RS} (30, 30*). However, the mask patterns 220d, 220e corresponding to the new contents are written into the reserved mask-region 260B*. Accordingly, the memory cells in the area 240B* of the memory level 200 stores the new contents.

To lower the manufacturing cost, the memory levels (e.g. 200) storing empty blocks (or, the memory levels storing up-to-date contents in the updated 3D-MPROM_{RS} 30*) are preferably formed above the memory levels (e.g. 100) storing no empty blocks (or, the memory levels storing no up-to-date contents in the updated 3D-MPROM_{RS} 30*). Moreover, to simplify the data-mask management, the reserved mask-regions are preferably consolidated into the least number of data-masks.

In the preferred embodiment of FIGS. 8A-9B, only a partial memory level is reserved for the new contents. In fact, a whole memory level can be reserved for the new contents. Accordingly, the present invention discloses a three-dimensional mask-ROM with reserved memory level(s) (3D-MPROM_{RL}). When fully manufactured, a 3D-MPROM_{RL} comprises X (X is a positive integer) memory levels, among which the topmost Y (Y is a positive integer, Y<X) memory levels are reserved for the new contents. The 3D-MPROM_{RL} only contains enough memory levels for the required contents. To be more specific, the original 3D-MPROM_{RL} is partially manufactured and comprises only the lowermost Z (Z is a positive integer, Z=X−Y) memory levels (i.e. original memory levels), which store the original contents. The updated 3D-MPROM_{RL} is fully manufactured and comprises all X memory levels, with the reserved Y memory levels formed on top of the original Z memory levels and storing the new contents.

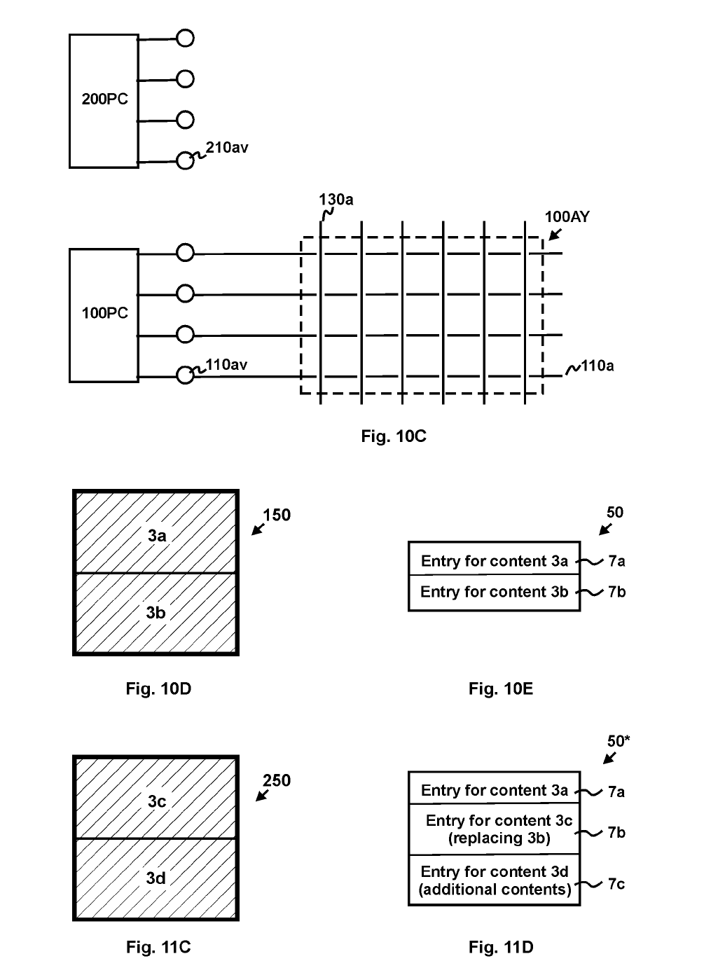

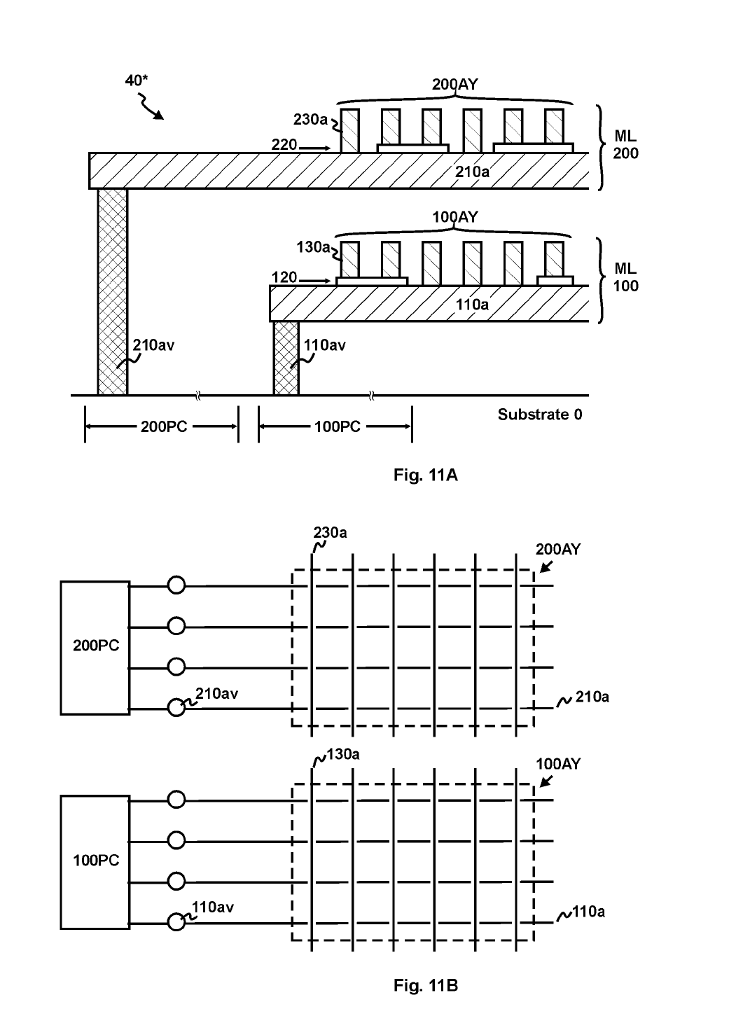

FIGS. 10A-11D disclose a preferred 3D-MPROM_{RL}. In this preferred embodiment, the fully-manufactured 3D-MPROM_{RL} comprises two memory levels, with the lowermost (i.e. first) memory level (i.e. the original memory level) storing the original contents, and the topmost (i.e. second) memory level (i.e. the reserved memory level) reserved for new contents.

FIGS. 10A-10E disclose various aspects of the original 3D-MPROM_{RL} 40. FIG. 10A is its cross-sectional view. The original 3D-MPROM_{RL} only comprises the first memory level 100. The memory cells at the memory level 100 form a memory array 100AY. Attention needs to be paid to the fact that the second memory level is absent in the original 3D-MPROM_{RL} 40. The first memory level 100 stores the original contents, which are defined by the data-layer 120. The peripheral circuit 100PC for memory level 100 is formed in the substrate 0. It is coupled with the first memory level 100 through the contact vias (110av . . . ). The contact via 210av for the second memory level is formed up to the first memory level 100, but not coupled with any memory level.

FIG. 10B is a top view of the substrate 0 for the original 3D-MPROM_{RL} 40. It comprises the first peripheral circuit 100PC for the memory level 100, as well as the second peripheral circuit 200PC for the second memory level. In this figure, only the peripheral circuits for one address-line direction are drawn, while the peripheral circuits for the other address-line direction are not drawn. Note that, even though the reserved (second) memory level is absent in the original 3D-MPROM_{RL}, its peripheral circuit 200PC is still formed in the substrate because the substrate circuits for all versions of the 3D-MPROM_{RL} are defined by the same mask set. The projected image of the memory array 100AY on the substrate 0 is also drawn in this figure. It can be observed that, with respect to the memory array 100AY, the peripheral circuit 200PC for the higher memory level is generally located on the outside of the peripheral circuit 100PC for the lower memory level.

FIG. 10C is its circuit block diagram for the original 3D-MPROM_{RL} 40. The first peripheral circuit 100PC is coupled to the memory array 100AY. The data stored in the memory array 100AY can be read out through the first peripheral circuit 100PC. For reason of simplicity, memory cells and their components (e.g. diodes) are not shown in this figure. The second peripheral circuit 200PC is not coupled to any memory array. Note that, the original 3D-MPROM_{RL}, even though partially manufactured, is fully functional and can be read by a data-reading device.

FIG. 10D illustrates the data-mask 150 for the memory level 100. In this example, the data-mask 150 comprises two mask-regions, which store the original contents 3a, 3b. FIG. 10E discloses a pointer file 50 for the original 3D-MPROM_{RL} 40. It comprises two entries 7a, 7b, with the entry 7a pointing to the content 3a and the entry 7b pointing to the content 3b.

FIGS. 11A-11D disclose various aspects of the updated 3D-MPROM_{RL} 40*. FIG. 11A is its cross-sectional view. The updated 3D-MPROM_{RL} is fully manufactured up to the memory level 200, which is on top of the original memory level 100. The memory cells at the memory level 200 form a memory array 200AY. The second memory level 200 stores the new contents, which are defined by the data-layer 220. The contact via 210av is extended and couples the second memory level 200 with its peripheral circuit 200PC.

FIG. 11B is the circuit block diagram for the updated 3D-MPROM_{RL} 40*. Note that the substrate circuits are the same for the original and updated versions of the 3D-MPROM_{RL}. The second peripheral circuit 200PC is coupled to the memory array 200AY. The data stored in the memory array 200AY can be read out through the second peripheral circuit 200PC. For reason of simplicity, memory cells and their components (e.g. diodes) are not shown in this figure.

FIG. 11C illustrates the data-mask 250 for the second memory level 200. In this example, the data-mask 250 comprises two mask-regions, which store the new contents 3c, 3d. Here, the content 3c is to replace the out-of-date content 3b, while the extra content 3d is added to the original contents. FIG. 11D discloses an updated pointer file 50*. It comprises three entries 7a-7c. Among them, the entry 7a still points to the content 3a; the entry 7b, originally pointing to the out-of-date content 3b, now points to the up-to-date content 3c; and the entry 7c points to the extra content 7d. It should be apparent to those skilled in the art that the file system of FIGS. 6A-7B can be applied to the 3D-MPROM_{RL}.

The 3D-MPROM_{RL} is particularly advantageous for incremental content release. The original data-mask 150 is not discarded and still usable for the updated 3D-MPROM_{RL}, while the new data-mask 250 contains only the new contents. Hence, every content on these data-masks is utilized to its full potential. In addition, because the new contents are stored in the memory level 200, which is formed above (NOT BESIDE) the memory level 100, no chip real estate in the original 3D-MPROM_{RL} is allocated for the new contents. Hence, every chip real estate is utilized to its full potential. In sum, the 3D-MPROM_{RL} can minimize extra mask cost and extra chip cost from content revision.

While illustrative embodiments have been shown and described, it would be apparent to those skilled in the art that may more modifications than that have been mentioned above are possible without departing from the inventive concepts set forth therein. The invention, therefore, is not to be limited except in the spirit of the appended claims.

What is claimed is:

1. A mask-programmed read-only memory (mask-ROM), comprising:
a plurality of mask-ROM cells storing at least two versions of a content, including an out-of-date version and an up-to-date version;
whereby said up-to-date version is read out instead of said out-of-date version.

2. The mask-ROM according to claim 1, wherein said mask-ROM further stores a single version of permanent contents.

3. The mask-ROM according to claim 1, further comprising a pointer to the memory address of said up-to-date version of said content.

4. The mask-ROM according to claim 1, wherein said mask-ROM stores at least a multimedia content or a computer program.

5. The mask-ROM according to claim 1, wherein said mask-ROM stores at least a movie, a TV program, or a video game.

6. The mask-ROM according to claim 1, wherein said mask-ROM is a three-dimensional mask-ROM (3D-MPROM).

7. The mask-ROM according to claim 6, wherein the memory level of said 3D-MPROM storing up-to-date contents is stacked above the memory level of said 3D-MPROM storing no up-to-date contents.

8. A mask-programmed read-only memory (mask-ROM), comprising:
an original data space; and
a reserved space, wherein said reserved space comprises all empty blocks of said mask-ROM and has a total size larger than 30MB.

9. The mask-ROM according to claim 8, wherein of said reserved space has a total size large than 100 MB.

10. The mask-ROM according to claim 8, wherein said reserved space is large enough to store at least one standalone content.

11. The mask-ROM according to claim 10, wherein said standalone content is a multimedia content or a computer program.

12. The mask-ROM according to claim 10, wherein said standalone content is a movie, a TV program or a video game.

13. The mask-ROM according to claim 8, wherein said mask-ROM is a three-dimensional mask-ROM (3D-MPROM).

14. The mask-ROM according to claim 13, wherein the memory level of said 3D-MPROM storing at least one empty block is stacked above the mask-ROM level of said 3D-MPROM storing no empty block.

15. A three-dimensional mask-programmed read-only memory (3D-MPROM), comprising:
a semiconductor substrate comprising a first peripheral circuit for a first memory array and a second peripheral circuit for a second memory array;
a first memory level stacked above said semiconductor substrate and coupled with said first peripheral circuit, said first memory level comprising said first memory array;
wherein said second peripheral circuit is not coupled with any memory array.

16. The 3D-MPROM according to claim 15, wherein said second peripheral circuit is formed on the outside of said first peripheral circuit with respect to said first memory array.

17. The 3D-MPROM according to claim 15, wherein said 3D-MPROM can be read by a data-reading device.

18. The 3D-MPROM according to claim 15, wherein said 3D-MPROM stores at least a multimedia content or a computer program.

19. The 3D-MPROM according to claim 15, wherein said 3D-MPROM stores at least a movie, a TV program, or a video game.

20. The 3D-MPROM according to claim 15, wherein a second memory level comprising said second memory array can be formed above said first memory level and coupled with said second peripheral circuit in the updated 3D-MPROM.
